(19) United States
(12) Patent Application Publication
(10) Pub. No.: US 2026/0239924 A1
(43) Pub. Date: Aug. 13, 2026

(54) MAGNETIC Z-ACTUATOR AND WAFER HOLDER COMPRISING SUCH ACTUATOR

(71) Applicant: ETEL S.A., Môtiers (CH)

(72) Inventors: Manish MITTAL, Neuchâtel (CH); Iván GARCIA-HERREROS, Fleurier (CH)

(21) Appl. No.: 19/531,809

(22) Filed: Feb. 6, 2026

(30) Foreign Application Priority Data
Feb. 12, 2025 (EP) 25157429.9

(51) Int. Cl. H10P 72/76

(52) U.S. Cl. CPC H10P 72/7612

(57) ABSTRACT

A magnetic Z-actuator for payload positioning, with gravity compensation, includes a stationary assembly and a mobile assembly configured to move relative to the stationary assembly. The stationary assembly includes a tubular magnetic yoke and at least one upper permanent magnet and at least one lower permanent magnet mounted against an inner wall of the magnetic yoke on top of each other. Each of the at least one upper and lower permanent magnets is either annular in shape, extending along the entire inner circumference of the magnetic yoke, or arcuate in shape, extending along a portion of the inner circumference. The at least one upper permanent magnet has a radial magnetization opposite to that of the at least one lower permanent magnet. The mobile assembly includes a magnetic yoke, at least one permanent magnet, which is either annular in shape and positioned around the magnetic yoke or arcuate in shape, covering a portion of the yoke's circumference, and at least one coil mounted around the magnetic yoke. The stationary and mobile assemblies are configured to hold the payload in a stable position by counteracting gravity. The at least one coil is arranged to be energized such that the mobile assembly is moved upwardly or downwardly relative to the stationary assembly. A wafer holder may include the magnetic Z-actuator, and a piece of semiconductor equipment may include such a wafer holder.

### CROSS-REFERENCE TO RELATED APPLICATIONS

The present application claims priority to Application No. 25157429.9, filed in the European Patent Office on Feb. 12, 2025, which is expressly incorporated herein in its entirety by reference thereto.

### FIELD OF THE APPLICATION

The present application relates to a magnetic Z-actuator for semiconductor equipment, e.g., a wafer holder, including, for example, a stationary assembly and a mobile assembly configured to move in a Z-direction relative to the stationary assembly. The Z-actuator includes, for example, an adjustable gravity compensator to adjust the gravity counteracting force to adapt to the weight variation of the payload.

### BACKGROUND INFORMATION

In certain applications, such as in the production of semiconductors, many wafer tables that are used to support and to process wafers are typically able to move in the vertical Z-direction. The weight of such wafer tables needs to be supported against the force of gravity by one or more gravity-compensation devices to reduce or eliminate the effect of the gravity force.

Conventional devices typically consist of a passive gravity compensator unit combined with multiple voice coil motors, which significantly increase the system's bulk and complexity. For example, U.S. Pat. No. 9,172,291 describes a magnetic Z-actuator with gravity compensation offering a more compact approach. However, a key limitation of this design lies in the gravity compensation force, which varies over the stroke due to its inherent negative stiffness. To counteract this issue, flexural elements with positive stiffness are introduced to stabilize the system. While effective in certain applications, these flexural elements impose structural constraints as the mobile assembly cannot move in the XY direction relative to the stationary assembly.

The use of flexural elements in such magnetic Z-actuator makes it incompatible with systems that require full six-degree-of-freedom (6 DoF) motion, such as wafer tables. This limitation arises because flexural elements, while effective in providing stiffness compensation, inherently restrict motion in certain degrees-of-freedom. By creating a stiff fixing between the stationary and mobile assemblies in these degrees-of-freedom, they also transmit disturbing forces causing vibrations of the payload. As a result, their use compromises the overall precision and stability required for high-performance positioning applications.

### SUMMARY

Example embodiments described in the present application provide a magnetic Z-actuator for payload positioning, with gravity compensation, that, for example, overcomes the shortcomings and limitations of conventional systems.

For example, the magnetic Z-actuator provides for a gravity compensation force that remains substantially constant over stroke.

Additionally, a high-precision magnetic Z-actuator is described herein that is compatible with systems requiring full six-degree-of-freedom motion.

Moreover, a magnetic Z-actuator is described herein having adjustable gravity compensation as a function of the weight of the payload.

According to example embodiments, a magnetic Z-actuator for payload positioning, with gravity compensation, includes a stationary assembly and a mobile assembly configured to move relative to the stationary assembly. The stationary assembly includes a tubular magnetic yoke, and at least one upper permanent magnet and at least one lower permanent magnet mounted against an inner wall of the magnetic yoke on top of each other. Each of the at least one upper and lower permanent magnets is either annular in shape, extending along the entire inner circumference of the magnetic yoke, or arcuate in shape, extending along a portion of the inner circumference. The at least one upper permanent magnet has a radial magnetization opposite to that of the at least one lower permanent magnet. The mobile assembly includes a magnetic yoke, at least one permanent magnet, which is either annular in shape and positioned around the magnetic yoke or arcuate in shape, covering a portion of the yoke's circumference, and at least one coil mounted around the magnetic yoke. The stationary and mobile assemblies are configured to hold the payload in a stable position by counteracting gravity. The at least one coil is arranged to be energized such that the mobile assembly is moved upwardly or downwardly relative to the stationary assembly.

According to example embodiments, the at least one upper permanent magnet includes a first pair of two diametrically opposed arcuate permanent magnets, and the at least one lower permanent magnet includes a second pair of diametrically opposed arcuate permanent magnets. The magnets of each pair share the same radial magnetization, whereas the second pair's radial magnetization is oriented in the opposite direction to that of the first pair.

According to example embodiments, the first pair of two diametrically opposed arcuate permanent magnets is angularly aligned with the second pair of diametrically opposed arcuate permanent magnets.

According to example embodiments, each arcuate permanent magnet of each pair extends over a range of 90° to 150°, e.g., between 110° and 130°.

According to example embodiments, the mobile assembly includes two coils arranged on both sides of either one complete or incomplete annular-shaped permanent magnet or two diametrically opposed arcuate permanent magnets.

According to example embodiments, each of the diametrically opposed arcuate permanent magnets extends over a range of 90° to 150°, e.g., between 110° and 130°.

According to example embodiments, the complete or incomplete annular-shaped permanent magnet or each of the diametrically opposed arcuate permanent magnets of the mobile assembly has a radial magnetization.

According to example embodiments, the magnetic Z-actuator further includes a cylindrical housing. The tubular magnetic yoke is fitted inside the cylindrical housing so that it can be rotated relative to the housing and around the mobile assembly to adjust the gravity compensation force.

According to example embodiments, the annular upper side of the tubular magnetic yoke includes a tool cooperation device to rotate it around the mobile assembly with a tool.

According to example embodiments, the magnetic Z-actuator further includes a clamp mounted on the cylindrical housing and configured to press on the annular upper side of the tubular magnetic yoke to block it in a given angular position.

According to example embodiments, the annular bottom side of the tubular magnetic yoke is resting against a shoulder provided on the inner wall of the cylindrical housing.

According to example embodiments, one of the upper annular side of the cylindrical housing and of the upper annular side of the magnetic yoke of the stationary unit includes at least one graduation extending over at least 40°, e.g., over 60°. The other of the upper annular side of the cylindrical housing and upper annular side of the magnetic yoke of the stationary unit includes at least one mark configured to be moved along the graduation.

According to example embodiments, one end of magnetic yoke of the mobile assembly is configured to be connected to the payload.

According to example embodiments, a wafer holder includes a magnetic Z-actuator as described herein.

According to example embodiments, a piece of semiconductor equipment includes a wafer holder as described herein.

Further features and aspects of example embodiments of the present application are described in more detail below with reference to the appended schematic Figures.

### BRIEF DESCRIPTION OF THE DRAWINGS

FIG. 1 is a perspective view of a magnetic Z-actuator with an adjustable gravity compensator.

FIG. 2 is a top view of the magnetic Z-actuator.

FIG. 3 is an exploded view of the magnetic Z-actuator.

FIG. 4 is a perspective view of a stationary assembly of the magnetic Z-actuator, in which the arcuate permanent magnets are represented by dashed lines.

FIGS. 5 and 6 are perspective views of the stationary assembly and a mobile assembly of the magnetic Z-actuator, respectively, without an adjustable gravity compensator.

FIG. 7 is a cross-sectional view of the magnetic Z-actuator illustrating its operational principle.

FIG. 8 is a chart illustrating a constant gravity compensation force over a stroke of the mobile assembly within a range of ±0.5 mm.

FIG. 9 is a chart illustrating the distribution of various forces based on the operational principle of the magnetic Z-actuator illustrated in FIG. 7, plotted over the stroke of the mobile assembly.

FIG. 10 is a simplified top view of the magnetic Z-actuator, illustrated in FIG. 1, highlighting the adjustable angular angle between the stationary and mobile assemblies.

FIG. 11 is a chart illustrating the variation of the gravity compensation force as a function of the angle illustrated in FIG. 10.

### DETAILED DESCRIPTION

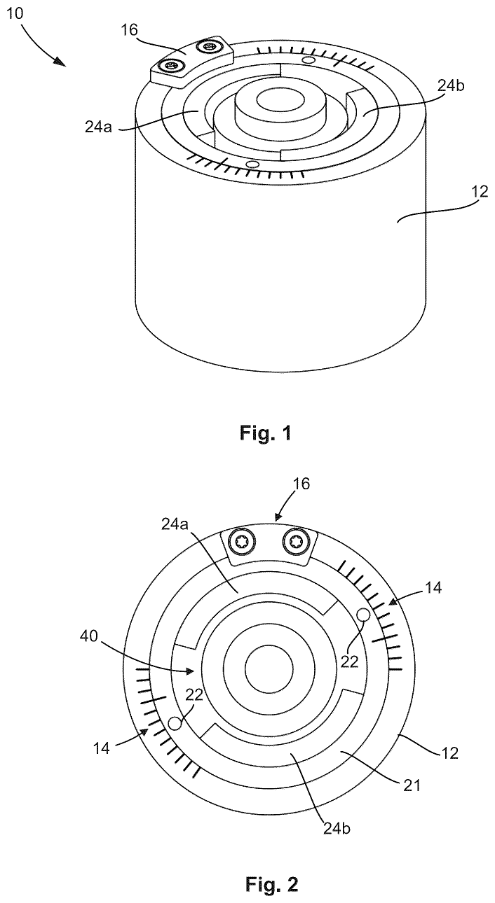

According to example embodiments, and with reference to FIGS. 1 to 3 and 7, a magnetic Z-actuator 10 for payload positioning is configured to provide gravity compensation, counteracting the force F_{PL} exerted by the weight of the payload. In this respect, the magnetic Z-actuator 10 includes a stationary assembly 20 and a mobile assembly 40, which is mounted within the stationary assembly 20. As explained in more detail below, the stationary and mobile assemblies include a set of permanent magnets arranged and positioned relative to each other to generate a counteracting force F_{counter} that sustains the payload in a stable position corresponding to an equilibrium state. The mobile assembly further includes coils 44a, 44b that are configured to be energized to move the mobile assembly upwardly or downwardly relative to the stationary assembly, as explained in more detail below.

The magnetic Z-actuator 10 is particularly well-suited for semiconductor equipment, such as a wafer stage that is held by gravity compensation in the equilibrium state and in which the coils 44a, 44b are energized for accurate positioning of the stage, e.g., during wafer inspection, where the camera's shallow depth of field necessitates fine-tuning of the stage's vertical position to achieve autofocus.

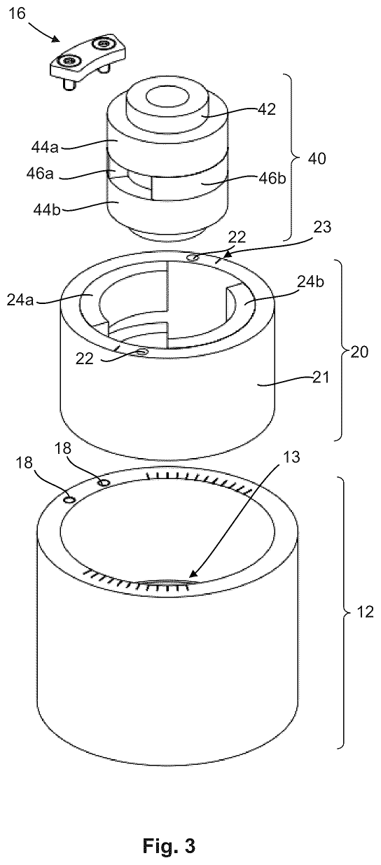

The stationary assembly 20 includes a tubular magnetic yoke 21 mounted inside a cylindrical housing 12, with its bottom side resting against a shoulder 13 (see, e.g., FIG. 3), which, for example, extends around the entire inner circumference of the housing 12. The position of the annular shoulder 13 within the housing 12 and the height of the magnetic yoke 21 ensures that its upper annular side extends slightly above the upper annular side of the housing 12, for reasons explained further below.

An angular adjustable positioning of the stationary assembly 20 relative to the mobile assembly 40 provides for varying the counteracting force F_{counter} according to the payload weight variation.

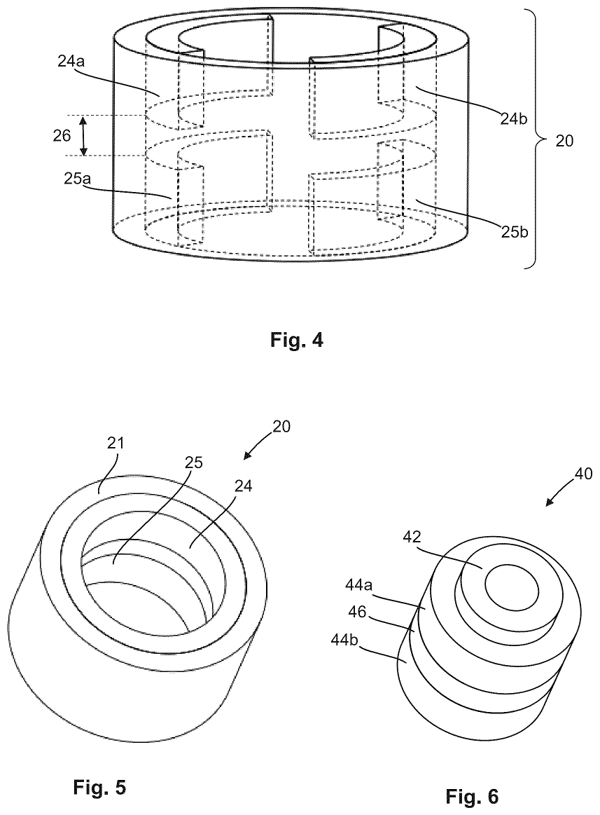

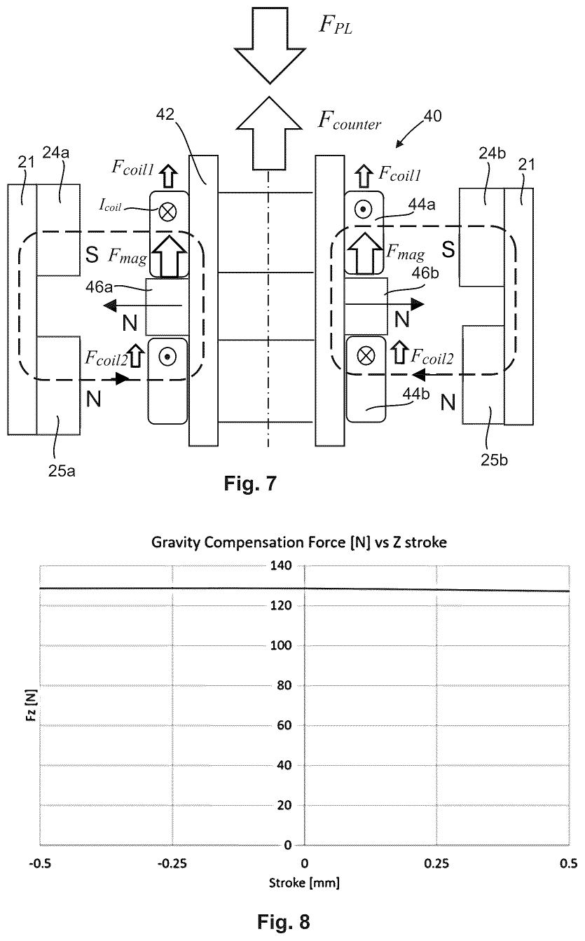

In this respect, referring, for example, to FIG. 7, the magnetic yoke 21 includes a first pair and a second pair of arcuate permanent magnets 24a, 24b, 25a, 25b. The first pair of permanent magnets 24a, 24b are mounted against the upper inner wall portion of the magnetic yoke 21, positioned diametrically opposite each other. The second pair of permanent magnets 25a, 25b are mounted against the lower inner wall portion of the magnetic yoke, also diametrically opposed and aligned with the first pair. There is a gap 26 between the first and second pairs of permanent magnets (see, e.g., FIG. 4) at the level of the permanent magnets 46a, 46b of the mobile assembly 40.

The arcuate permanent magnets of each pair share the same radial magnetization, while the radial magnetization of the first pair is oriented in the opposite direction to that of the second pair. For example, the first pair of diametrically opposed permanent magnets 24a, 24b has a positive radial magnetization, while the second pair of diametrically opposed permanent magnets 25a, 25b has a negative radial magnetization.

As illustrated, for example, in FIGS. 2 and 4, each of the first pair of arcuate magnets 24a, 24b, as well as each of the second pair of arcuate magnets 25a, 25b, extends over a range of 90° to 150°, e.g., between 110° and 130°, for example, approximately 120°.

The mobile assembly 40 includes a cylindrical or tubular magnetic yoke 42, two diametrically opposed arcuate permanent magnets 46a, 46b arranged around a middle portion of the magnetic yoke 42, and two coils mounted around the magnetic yoke 42 on both sides of the permanent magnets. Each of these two arcuate permanent magnets 46a, 46b has a positive radial magnetization and extends over a range between 90° and 150°, e.g., between 110° and 130°, for example, approximately 120°.

As illustrated in FIG. 2, the annular upper side of tubular magnetic yoke 21 includes a tool cooperation feature 22 for its rotation around the mobile assembly 40. The tool cooperation feature may be, for example, in the form of two holes 22, diametrically opposed, so that two pins of a tool can be fitted into these holes for rotation of the stationary assembly 20 within the cylindrical housing 12 and relative to the mobile assembly 40.

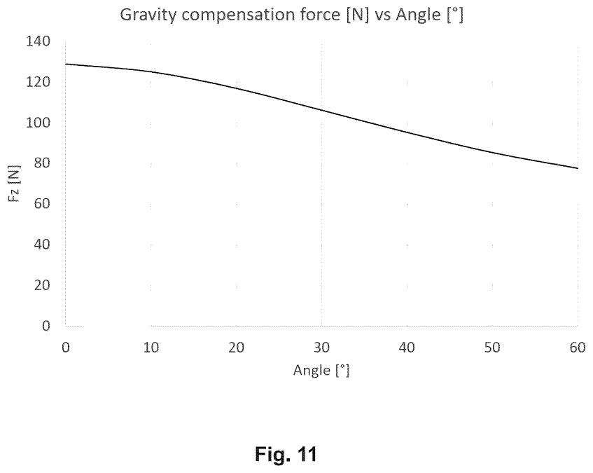

Referring to FIGS. 10 and 11, according to the configuration described above, the maximal gravity counteracting force F_{counter} is set at 130 N and decrease down to 80 N for a relative angular movement of 60° between the stationary assembly 20 and the mobile assembly 40.

The magnetic Z-actuator 10 further includes a clamp 16 mounted on the cylindrical housing 12 and configured to press on the annular upper side of the tubular magnetic yoke 21, which is slightly higher than the housing top side, in order to block the magnetic yoke in a given angular position for the desired gravity counteracting force. The clamp 16 may include, for example, two screws fitted into two corresponding threaded holes 18 provided on the upper annular side of the housing 12, as illustrated in FIG. 3.

The upper annular side of the cylindrical housing 12 further includes two graduations diametrically opposed and extending each over at least 40°, e.g., over 60°. The upper side of the tubular magnetic yoke 21 of the stationary unit 20 includes two diametrically opposed marks 23 arranged to be moved along the corresponding graduation for precise adjustment of the gravity compensating force F_{counter}. The graduations may indicate the angle or force level.

According to example embodiments, the two graduations 14 are disposed in a diametrically opposed manner along the upper annular side of the magnetic yoke 21 of the stationary unit 20, and the two marks 23 are disposed on the upper annular side of the cylindrical housing 12. According to example embodiments, the housing 12 and the magnetic yoke 21 may include only one graduation and one mark respectively.

As illustrated in FIG. 7, the upper end of the magnetic yoke 42 is configured to be connected to the payload. The upper coil 44a and lower coil 44b are energized to move the mobile assembly 40 in vertical direction upwardly or downwardly using Lorentz force. Since the gravity counteracting force F_{counter} compensates for the payload weight that sustains a stable position corresponding to an equilibrium state, only a low current is required to move and keep position within the operating range. This limits Joule losses and heat generation in the coils and the overall system, leading to high precision.

According to the illustrated example embodiment, to move the mobile assembly 40 upwardly, the upper and lower coils 44a, 44b must be energized such that the current flows in a clockwise direction through the upper coil 44a and in a counterclockwise direction through the lower coil 44b. Conversely, to move the mobile assembly 40 downwardly, the upper and lower coils 44a, 44b must be energized such that the current flows in a counterclockwise direction through the upper coil 44a and in a clockwise direction through the lower coil 44b.

FIGS. 5 and 6 illustrate the stationary assembly 20 and a mobile assembly 40 of a magnetic Z-actuator without an adjustable gravity compensator according to an example embodiment. In this respect, the first and second permanent magnets 24, 25 are annular in shape, extending along the entire inner circumference of the magnetic yoke 21. The mobile assembly 40 includes a permanent magnet 46, which is also annular in shape arranged in a middle portion of the magnetic yoke 42 between two coils 44a, 44b. The magnetic Z-actuator, according to this example embodiment, is configured to maximize the gravity counteracting force, making it suitable for applications where the payload has substantial weight.

The magnetic interaction between the permanent magnets 46a, 46b of the mobile assembly 40 and the arcuate magnets 24a, 24b, 25a, 25b of the stationary assembly 20 generates a vertical force that contributes to gravity compensation. This vertical force remains constant over a specific range, ensuring stable support for the moving components. For example, the Z-actuator of the illustrated example embodiment provides a consistent gravity compensation force of 128 N across a displacement range of ±0.5 mm, as illustrated in FIG. 8.

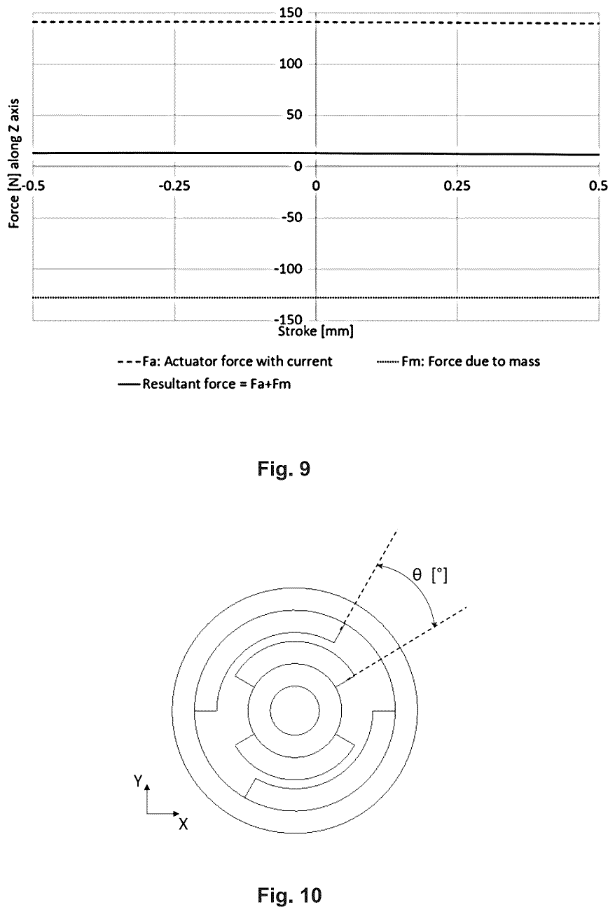

FIG. 9 illustrates the various forces acting on the magnetic Z-actuator in any of the aforementioned example embodiments. The total force Fa generated by the actuator is a combination of the reluctance force and the Lorentz force, the latter being directly proportional to the current flowing through the coils. Additionally, the gravitational force Fm, which results from the mass of the moving assembly, must be compensated for by the actuator to ensure stable operation.

Various modifications and variations to the above-described example embodiments may be made without departing from the spirit and scope hereof. For example, the magnetic Z-actuator may include only one coil to drive the mobile assembly upwardly and downwardly.

### LIST OF REFERENCE NUMERALS

10 Z-actuator
12 Cylindrical-housing
13 Shoulder
14 Graduation
16 Clamp
18 Holes
20 Stationary assembly
21 Tubular magnetic yoke
22 Holes
23 Mark
24a, 24b First pair of permanent magnets
25a, 25b Second pair of permanents magnets
26 Gap
40 Mobile assembly
42 Magnetic yoke
44, 44a, 44b Coils
46, 46a, 46b Permanent magnet

What is claimed is:

1. A magnetic Z-actuator for payload positioning, with gravity compensation, includes:
a stationary assembly including a tubular magnetic yoke, and at least one upper permanent magnet and at least one lower permanent magnet mounted against an inner wall of the tubular magnetic yoke on top of each other, each upper permanent magnet and each lower permanent magnets being (a) annular in shape and extending along an entire inner circumference of the tubular magnetic yoke or (b) arcuate in shape and extending along a portion of the inner circumference of the tubular magnetic yoke, the upper permanent magnet having a radial magnetization opposite to a radial magnetization of the lower permanent magnet; and
a mobile assembly movable relative to the stationary assembly and including a magnetic yoke, at least one permanent magnet that is (a) annular in shape and positioned around the magnetic yoke or (b) arcuate in shape and covering a portion of a circumference of the magnetic yoke, and at least one coil mounted around the magnetic yoke, the coil configured to be energized to move the mobile assembly upwardly and downwardly relative to the stationary assembly;
wherein the stationary assembly and the mobile assembly are configured to hold the payload in a stable position by counteracting gravity.

2. The magnetic Z-actuator according to claim 1, wherein the upper permanent magnet includes a first pair of diametrically opposed arcuate permanent magnets, the lower permanent magnet includes a second pair of diametrically opposed arcuate permanent magnets, the permanent magnets of each pair sharing a same radial magnetization, the radial magnetization of the second pair being oriented in an opposite direction to the radial magnetization of the first pair.

3. The magnetic Z-actuator according to claim 2, wherein the first pair is angularly aligned with the second pair.

4. The magnetic Z-actuator according to claim 2, wherein each arcuate permanent magnet of each pair extends over a range of 90° to 150°.

5. The magnetic Z-actuator according to claim 2, wherein each arcuate permanent magnet of each pair extends over a range of 110° to 130°.

6. The magnetic Z-actuator according to claim 1, wherein the at least one coil of the mobile assembly includes two coils, a first one of the two coils being arranged on a first side of the permanent magnet of the mobile assembly, a second one of the two coils being arranged on a second side of the permanent magnet of the mobile assembly.

7. The magnetic Z-actuator according to claim 6, wherein the permanent of the mobile assembly includes two diametrically opposed arcuate permanent magnets that extend over a range of 90° to 150°.

8. The magnetic Z-actuator according to claim 6, wherein the permanent of the mobile assembly includes two diametrically opposed arcuate permanent magnets that extend over a range of 110° to 130°.

9. The magnetic Z-actuator according to claim 1, wherein the permanent magnet of the mobile assembly has a radial magnetization.

10. The magnetic Z-actuator according to claim 1, further comprising a cylindrical housing, the tubular magnetic yoke being arranged inside the housing and being rotatable relative to the housing and around the mobile assembly to adjust a gravity compensation force.

11. The magnetic Z-actuator according to claim 10, wherein an annular upper side of the tubular magnetic yoke includes tool cooperation mechanism configured to rotate the tubular magnetic yoke around the mobile assembly.

12. The magnetic Z-actuator according to claim 10, further comprising a clamp mounted on the housing and configured to press on an annular upper side of the tubular magnetic yoke to secure the tubular magnetic yoke in a predefined angular position relative to the housing.

13. The magnetic Z-actuator according to claim 11, further comprising a clamp mounted on the housing and configured to press on an annular upper side of the tubular magnetic yoke to secure the tubular magnetic yoke in a predefined angular position relative to the housing.

14. The magnetic Z-actuator according to claim 10, wherein an annular bottom side of the tubular magnetic yoke rests against a shoulder located on an inner wall of the housing.

15. The magnetic Z-actuator according to claim 10, wherein an upper annular side of a first one of the housing and the tubular magnetic yoke includes at least one graduation extending over at least 40°, and the upper annular side of a second one of the housing and the tubular magnetic yoke includes at least one mark movable along the graduation.

16. The magnetic Z-actuator according to claim 15, wherein the graduation extends over 60°.

17. The magnetic Z-actuator according to claim 1, wherein one end of the magnetic yoke of the mobile assembly is configured to connect to the payload.

18. A magnetic Z-actuator for payload positioning, with gravity compensation, includes:
a stationary assembly including a tubular magnetic yoke, and at least one first permanent magnet and at least one second permanent magnet mounted against an inner wall of the tubular magnetic yoke on opposite axial sides of each other, each first permanent magnet and each second permanent magnets being (a) annular in shape and extending along an entire inner circumference of the tubular magnetic yoke or (b) arcuate in shape and extending along a portion of the inner circumference of the tubular magnetic yoke, the first permanent magnet having a radial magnetization opposite to a radial magnetization of the second permanent magnet; and
a mobile assembly movable relative to the stationary assembly and including a magnetic yoke, at least one permanent magnet that is (a) annular in shape and positioned around the magnetic yoke or (b) arcuate in shape and covering a portion of a circumference of the magnetic yoke, and at least one coil mounted around the magnetic yoke, the coil configured to be energized to move the mobile assembly in an axial direction relative to the stationary assembly;
wherein the stationary assembly and the mobile assembly are configured to hold the payload in a stable position by counteracting gravity.

19. A wafer holder, comprising:
the magnetic Z-actuator according to claim 1.

20. A piece of semiconductor equipment, comprising:
a wafer holder including the magnetic Z-actuator according to claim 1.
